(19) United States
(12) Patent Application Publication
(10) Pub. No.: US 2018/0081796 A1
(43) Pub. Date: Mar. 22, 2018

(54) Data Storage Device and Data Writing Method Thereof

(71) Applicant: Silicon Motion, Inc., Jhubei City (TW)

(72) Inventor: Shen-Ting Chiu, Houlong Township (TW)

(21) Appl. No.: 15/694,416

(22) Filed: Sep. 1, 2017

(30) Foreign Application Priority Data
Sep. 22, 2016 (TW) 105130573

(51) Int. Cl. G06F 12/02; G11C 16/10

(52) U.S. Cl. CPC G06F 12/0246; G06F 2212/2022; G11C 16/102

(57) ABSTRACT

The present invention provides a data storage device including a flash memory and a controller. The controller receives a plurality of write commands and a plurality of data sectors from the host. During the period of receiving the data sectors, the controller records that the received data sectors have not been confirmed when the total size of received data sectors has not yet reached a predetermined size, writes a plurality of specific data sectors of the data sectors, which have been received from the host, into the flash memory and transmits a plurality of write-confirm signals corresponding to the specific data sectors to the host when the total size of received data has reached the predetermined size.

### CROSS REFERENCE TO RELATED APPLICATIONS

This Application claims priority of Taiwan Patent Application No. 105130573, filed on Sep. 22, 2016, the entirety of which is incorporated by reference herein.

### BACKGROUND OF THE INVENTION

### Field of the Invention

The present invention relates to a data writing method of a data storage device, and in particular to a data writing method capable of executing a plurality of write commands at once.

### Description of the Related Art

Flash memory is considered a non-volatile data storage device, using electrical methods to erase and program itself. Taking NAND Flash as an example, it is often used in memory cards, USB flash devices, solid state devices, eMMC, and in other applications.

Flash memory such as NAND Flash uses a multiple-block structure to store data. Each block contains multiple pages, wherein the write unit of the flash memory is the page, and the erase unit of the flash memory is the block. In the specification of eMMC, the write command can be executed only when the previous write command is done. Namely, the data storage device can receive the data of the next write command from the host only once the current write command is finished. Therefore, a method of executing the write commands that increases the efficiency of the data storage device is needed.

### BRIEF SUMMARY OF THE INVENTION

A detailed description is given in the following embodiments with reference to the accompanying drawings.

An exemplary embodiment provides a data storage device including a flash memory and a controller. The controller receives a plurality of write commands arranged to write a plurality of data sectors into the flash memory from a host, receives the data sectors from the host in sequence according to the received write commands, wherein during the period of receiving the data sectors, the controller records that the received data sectors have not been confirmed when the total size of received data sectors has not reached a predetermined size, writes a plurality of specific data sectors of the data sectors, which have been received from the host, into the flash memory when the total size of received data has reached the predetermined size, and transmits a plurality of write-confirm signals corresponding to the specific data sectors to the host after all of the specific data sectors are written into the flash memory.

Another exemplary embodiment provides a data storage device including a flash memory and a controller. The controller receives a switch signal from a host, and operates in a cache-off mode of the specification of Universal Flash Storage or specification of Embedded Multi Media Card in response to the switch signal, wherein in the cache-off mode, the controller writes a plurality of specific data sectors, which are indicated by a plurality of first write commands, into the flash memory, and transmits a plurality of write-confirm signals corresponding to the first write commands to a host after all of the specific data sectors are written into the flash memory.

Another exemplary embodiment provides a data writing method applied to a data storage device having a flash memory. The data writing method includes receiving a plurality of write commands arranged to write a plurality of data sectors into the flash memory from a host; receiving the data sectors from the host in sequence according to the received write commands; recording the received data sectors that have not been confirmed when the total size of received data sectors has not reached a predetermined size; writing a plurality of specific data sectors of the data sectors, which have been received from the host, into the flash memory when the total size of received data has reached the predetermined size; and transmitting a plurality of write-confirm signals corresponding to the specific data sectors to the host after all of the specific data sectors are written into the flash memory.

Another exemplary embodiment provides a data writing method applied to a data storage device having a flash memory. The data writing method includes: receiving a switch signal from a host, and operating in a cache-off mode of the specification of Universal Flash Storage or specification of Embedded Multi Media Card in response to the switch signal, wherein in the cache-off mode the data writing method further includes: writing a plurality of specific data sectors, which are indicated by a plurality of first write commands, into the flash memory; and transmitting a plurality of write-confirm signals corresponding to the first write commands to a host after all of the specific data sectors are written into the flash memory.

### BRIEF DESCRIPTION OF THE DRAWINGS

The present invention can be more fully understood by reading the subsequent detailed description and examples with references made to the accompanying drawings, wherein:

FIG. 1 is a schematic diagram illustrating an electronic system in accordance with some embodiments.

FIG. 2 is a schematic diagram illustrating processes of data writing in accordance with an embodiment.

FIG. 3 is a schematic diagram illustrating processes of data writing in accordance with another embodiment.

FIGS. 4A˜4B are a flowchart of a data writing method in accordance with an embodiment.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

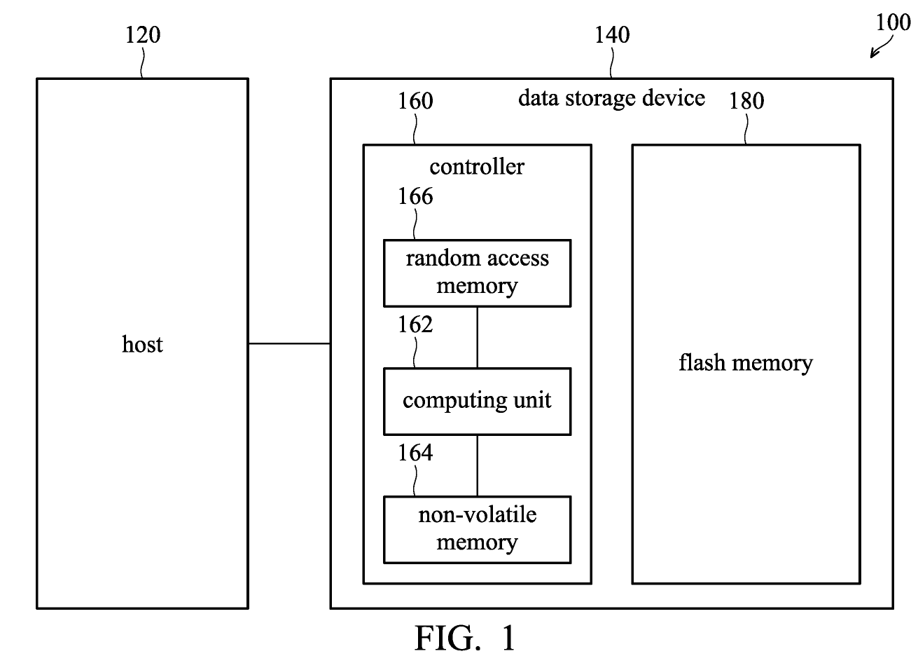

FIG. 1 is a schematic diagram illustrating an electronic system in accordance with some embodiments. The electronic system 100 includes a host 120 and a data storage device 140. The data storage device 140 includes a flash memory 180 and a controller 160, and operates in response to the commands of the host 120. It should be noted that, in an embodiment of the present invention, the data storage device 140 has to meet the specification of Embedded Multi Media Card (eMMC).

The controller 160 includes a computing unit 162, a non-volatile memory 164 (ROM), and a random access memory 166 (RAM). The non-volatile memory 164, the program code stored in the non-volatile memory 164 and data stored in the non-volatile memory 164 constitute firmware executed by the processing unit 162, and the controller 160 is configured to control the flash memory 180 based on the firmware. The random access memory 166 is arranged to temporarily store the data and cache data for the controller 160. Namely, the parameters, which are used to retrieve data by the controller 160, can be uploaded on the random access memory 166 for decreasing the busy time of the controller 160. It should be noted that the data storage device 140 has a busy flag arranged to represent whether the flash memory 180 is busy, wherein the busy flag can be implemented in the flash memory 180 or the random access memory 166. When the flash memory 180 is under a read operation or a write operation, the busy flag has a first predetermined value that represents a busy state. When the flash memory 180 is not under a read operation or a write operation, the busy flag has a second predetermined value that represents an idle state.

Both the specification of Embedded Multi Media Card and the specification of Universal Flash Storage (UFS) have a cache-off mode and a cache-on mode. In the cache-off mode, the data storage device 140 can transmit the write-confirm signal to the host 120 only after the data indicated by the write command is written in the flash memory 180 to notify the host that the data indicated by the corresponding write command is already written in the flash memory 180. Namely, in the cache-off mode, the action of transmitting the write-confirm signal to the host 120 means that the data of the write command is already written into the flash memory 180 of the data storage device 140. Thus the data will not be lost if an unexpected power-off occurs in the cache-off mode. In the cache-on mode, the data storage device 140 can transmit the write-confirm signal to the host 120 after temporarily storing the data, which is indicated by the write command and received from the host 120 in the random access memory 166. After transmitting the write-confirm signal to the host 120, the controller 160 writes the data temporarily stored in the random access memory 166 into the flash memory 180 according to a specific rule. Namely, in the cache-on mode, the action of transmitting the write-confirm signal to the host 120 of the data storage device 140 does not mean that the data is already written to the flash memory 180 of the data storage device 140. Thus, the data might be lost due to an unexpected power off event in the cache-on mode.

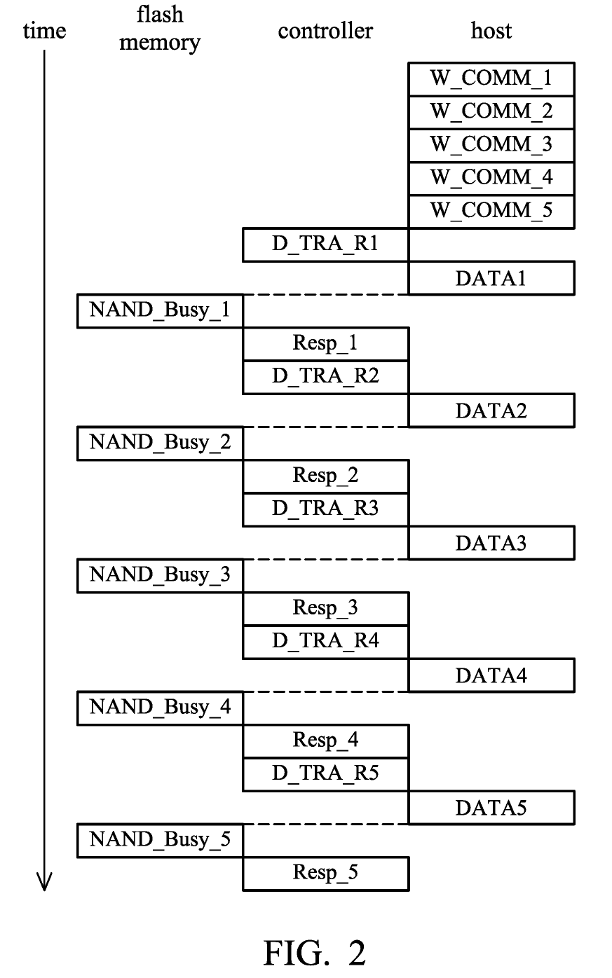

FIG. 2 is a schematic diagram illustrating processes of data writing in accordance with an embodiment. In FIG. 2, the data storage device 140 operates in the cache-off mode of the specification of Embedded Multi Media Card or the specification of Universal Flash Storage. First, the host 120 transmits a plurality of write commands W_COMM_1˜W_COMM_4 to the data storage device 140. After receiving the write commands W_COMM_1˜W_COMM_4, the controller 160 transmits a data-transmission request D_TRA_R1 corresponding to the write command W_COMM_1 to the host 120. After receiving the data-transmission request D_TRA_R1, the host 120 transmits the data sector DATA1 corresponding to the write command W_COMM_1 to the data storage device 140 in response to the data-transmission request D_TRA_R1. Next, the controller 160 writes the data sector DATA1 into the flash memory 180 in the busy period NAND_Busy_1. It should be noted that, at the time that the controller 160 starts to write the data sector DATA1 into the flash memory 180, the controller 160 or the flash memory 180 sets the busy flag as a busy state. Furthermore, when the data sector DATA1 is done writing into the flash memory 180, the controller 160 or the flash memory 180 sets the busy flag as an idle state. After setting the busy flag as an idle state, the controller 160 transmits the write-confirm signal Resp_1 to the host 120 to notify the host 120 that the data sector DATA1 indicated by the write command W_COMM_1 has been written into the flash memory 180. After transmitting the write-confirm signal Resp_1, the controller 160 transmits a data-transmission request D_TRA_R2 corresponding to the write command W_COMM_2 to the host 120. After receiving the data-transmission request D_TRA_R2, the host 120 transmits the data sector DATA2 corresponding to the write command W_COMM_2 to the data storage device 140. Next, the controller 160 writes the received data sector DATA2 into the flash memory 180 in the busy period NAND_Busy_2, wherein the controller 160 or the flash memory 180 sets the busy flag as a busy state at the time that the controller 160 starts to write the data sector DATA2 into the flash memory 180, and the controller 160 or the flash memory 180 sets the busy flag as an idle state at the time that the data sector DATA2 is done writing into the flash memory 180. After setting the busy flag as an idle state, the controller 160 transmits the write-confirm signal Resp_2 to the host 120 to notify the host 120 that the data sector DATA2 indicated by the write command W_COMM_2 has been written into the flash memory 180. Next, the controller 160 transmits a data-transmission request D_TRA_R3 corresponding to the write command W_COMM_3 to the host 120. After receiving the data-transmission request D_TRA_R3, the host 120 transmits the data sector DATA3 corresponding to the write command W_COMM_3 to the data storage device 140. Next, the controller 160 writes the received data sector DATA3 into the flash memory 180 in the busy period NAND_Busy_3, wherein the controller 160 or the flash memory 180 sets the busy flag as a busy state at the time that the controller 160 starts to write the data sector DATA3 into the flash memory 180, and the controller 160 or the flash memory 180 sets the busy flag as an idle state at the time that the data sector DATA3 is done writing into the flash memory 180. After setting the busy flag as an idle state, the controller 160 transmits the write-confirm signal Resp_3 to the host 120 to notify the host 120 that the data sector DATA3 indicated by the write command W_COMM_3 has been written into the flash memory 180. Next, the controller 160 transmits a data-transmission request D_TRA_R4 corresponding to the write command W_COMM_4 to the host 120. After receiving the data-transmission request D_TRA_R4, the host 120 transmits the data sector DATA4 corresponding to the write command W_COMM_4 to the data storage device 140. Next, the controller 160 writes the received data sector DATA4 into the flash memory 180 in the busy period NAND_Busy_4, wherein the controller 160 or the flash memory 180 sets the busy flag as a busy state at the time that the controller 160 starts to write the data sector DATA4 into the flash memory 180, and the controller 160 or the flash memory 180 sets the busy flag as an idle state at the time that the data sector DATA4 is done writing into the flash memory 180. After setting the busy flag as an idle state, the controller 160 transmits the write-confirm signal Resp_4 to the host 120 to notify the host 120 that the data sector DATA4 indicated by the write command W_COMM_4 has been written into the flash memory 180. Next, the controller 160 transmits a data-transmission request D_TRA_R5 corresponding to the write command W_COMM_5 to the host 120. After receiving the data-transmission request D_TRA_R5, the host 120 transmits the data sector DATA5 corresponding to the write command W_COMM_5 to the data storage device 140. Next, the controller 160 writes the received data sector DATA5 into the flash memory 180 in the busy period NAND_Busy_5, wherein the controller 160 or the flash memory 180 sets the busy flag as a busy state at the time that the controller 160 starts to write the data sector DATA5 into the flash memory 180, and the controller 160 or the flash memory 180 sets the busy flag as an idle state at the moment that the data sector DATA5 is done writing into the flash memory 180. After setting the busy flag as an idle state, the controller 160 transmits the write-confirm signal Resp_5 to the host 120 to notify the host 120 that the data sector DATA5 indicated by the write command W_COMM_5 has been written into the flash memory 180.

As described above, the controller 160 transmits the write-confirm signals to the host 120 after the corresponding data sector has been written into the flash memory 180. Therefore, the data storage device 140 has a stronger data protection ability in the cache-off mode. However, the minimum write unit of the flash memory 180 is a page. When the data indicated by the write command is less than a page, the controller 160 still needs to write the data into the flash memory 180 in units of pages. Thus, it decreases the write efficiency of the data storage device 140. For example, the size of page is 32 KB, the size of each of the data sectors DATA1˜DATA5 is 8 KB. Therefore, each of the busy periods NAND_Busy_1˜NAND_Busy_5 needs the same amount of time to write 8 KB of data into the flash memory 180 as writing 32 KB of data.

In view of this, the present invention provides another embodiment of writing data in the cache-off mode based on 11.3.14.3, 11.3.15.3 and 11.3.16.3 of the specification of Universal Flash Storage.

More specifically, the controller 160 receives a switch signal from the host 120, and operates in the cache-off mode of the specification of Embedded Multi Media Card or the specification of Universal Flash Storage in response to the switch signal. In the cache-off mode, the controller 160 receives a plurality of write commands from the host 120, and receives the data sectors indicated by the write commands from the host 120 one by one according to the received write commands. During the process of receiving data sectors, the controller 160 records that the received data sectors have not been confirmed when the total size of received data sectors has not reached a predetermined size. Namely, when the total size of received data sectors has not reached the predetermined size, the controller 160 records that the write-confirm signals of the received data sectors have not been transmitted to the host 120. In one of the embodiments, the status of whether the data sector is confirmed can be recorded in the random access memory 166 by specific bit values, but it is not limited thereto. In other embodiments, the status of whether the data sector is confirmed can be in other memory device, such as the flash memory 180, etc. When the size of received data sectors that have not been written into the flash memory 180 (specific data sectors) has reached the predetermined size, the controller 160 writes the specific data sectors into the flash memory 180. After all of the specific data sectors are written into the flash memory 180, the controller 160 transmits a plurality of write-confirm signals corresponding to the specific data sectors to the host 120, wherein during the period from writing the first one of the specific data sectors into the flash memory 180 to writing the last one of the specific data sectors into the flash memory 180, the busy flag maintains a busy status. Namely, the controller 160 receives a plurality of write commands arranged to write a plurality of data sectors into the flash memory 180 from the host 120, and writes the received data sectors by the unit of the predetermined size into the flash memory 180 in a busy period in a concentrated fashion. After the busy period, the controller 160 further transmits the write-confirm signals of the data sectors which are written in the busy period to the host 120 at the same time. It should be noted that, before the size of received data sectors has reached the predetermined size, the controller 160 records the status of the received data sectors that have not been written into the flash memory 180, such that the controller 160 may transmit the corresponding write-confirm signals to the host 120 according to the recorded statuses after the received data sectors reach the predetermined size and the received data sectors are written into the flash memory 180. In one embodiment, the predetermined size is equal to the size of the write unit (the minimum write unit) of the flash memory 180. For example, the write unit of the conventional flash memory 180 is a page, but it is not limited thereto. In other embodiments, the predetermined size may be designed according to the writing rule of the flash memory 180, wherein the minimum write unit of the flash memory 180 can also be a block or a sector.

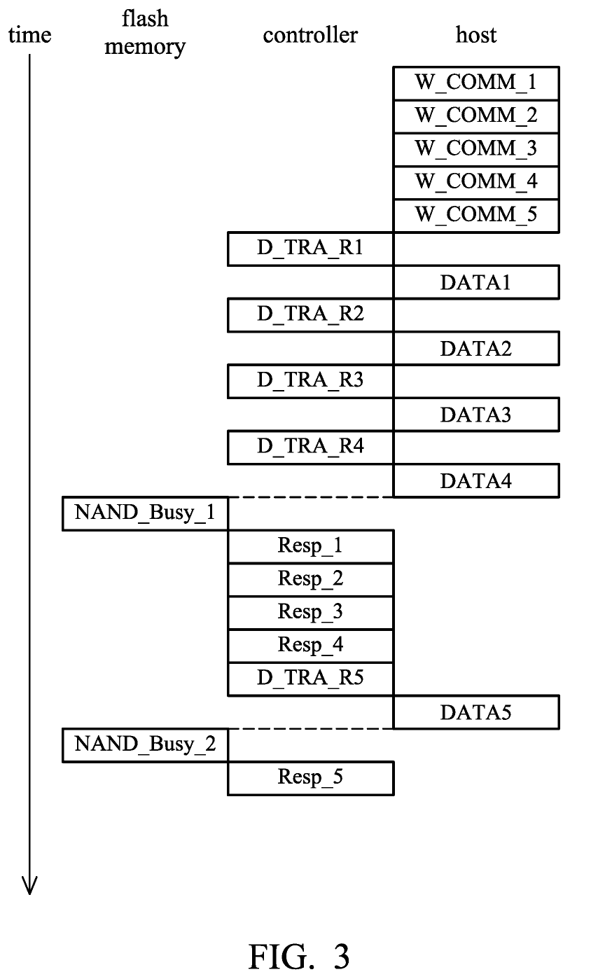

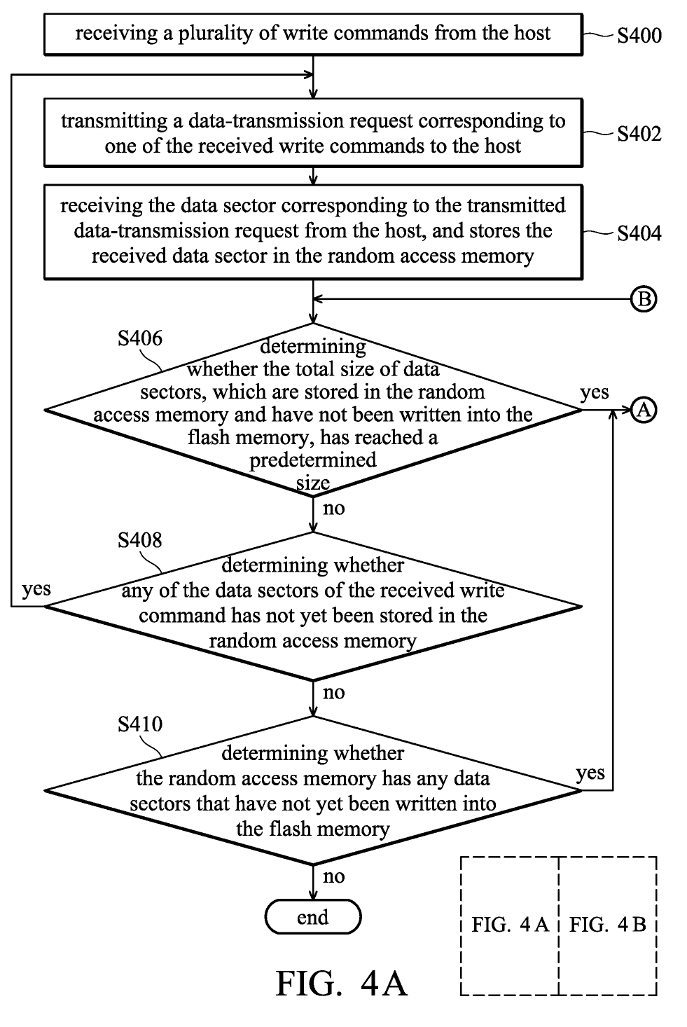

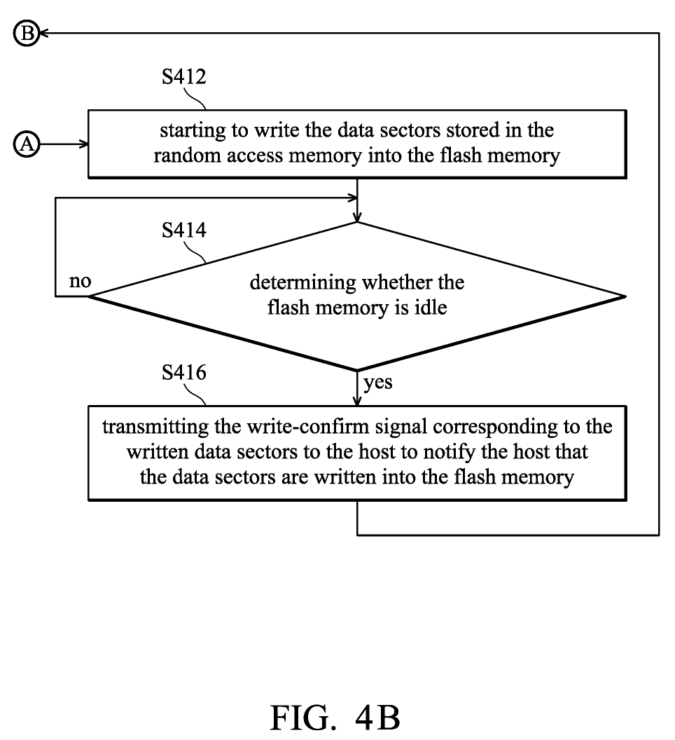

FIG. 3 is a schematic diagram illustrating processes of data writing in accordance with another embodiment. In FIG. 3, the data storage device 140 operates in the cache-off mode of the specification of the Embedded Multi Media Card or the specification of the Universal Flash Storage. First, the host 120 transmits a plurality of write commands W_COMM_1˜W_COMM_5 to the data storage device 140, wherein the write command W_COMM_1 is arranged to tell the data storage device 140 to write the data sector DATA1 into the flash memory 180, the write command W_COMM_2 is arranged to tell the data storage device 140 to write the data sector DATA2 into the flash memory 180, the write command W_COMM_3 is arranged to tell the data storage device 140 to write the data sector DATA3 into the flash memory 180, the write command W_COMM_4 is arranged to tell the data storage device 140 to write the data sector DATA4 into the flash memory 180, and the write command W_COMM_5 is arranged to tell the data storage device 140 to write the data sector DATA5 into the flash memory 180. It should be noted that, in this embodiment, the size of a page is 32 KB, and the size of each of the data sectors DATA1˜DATA5 is 8 KB, but it is not limited thereto. After receiving the write commands W_COMM_1˜W_COMM_5, the controller 160 transmits a data-transmission request D_TRA_R1 corresponding to the write command W_COMM_1 to the host 120. After receiving the data-transmission request D_TRA_R1, the host 120 transmits the data sector DATA1 corresponding to the write command W_COMM_1 to the data storage device 140. The controller 160 stores the received data sector DATA1 in the random access memory 166, and determines whether the data sector DATA1, which is stored in the random access memory 166 and has not yet been written into the flash memory, has reached a predetermined size. In this embodiment, the predetermined size is equal to the size of page. Namely, the size of data sector DATA1 “8 KB” is less than the predetermined size “32 KB”. Therefore, the controller 160 holds the write operation and does not write the data sector DATA1 into the flash memory 180 at this moment. Next, the controller 160 continues to transmit a data-transmission request D_TRA_R2 corresponding to the write command W_COMM_2 to the host 120. After receiving the data-transmission request D_TRA_R2, the host 120 transmits the data sector DATA2 corresponding to the write command W_COMM_2 to the data storage device 140. The controller 160 stores the received data sector DATA2 in the random access memory 166, and determines whether the data sectors DATA1˜DATA2, which are stored in the random access memory 166 and have not been written into the flash memory, have reached the predetermined size. The total size of data sectors DATA1˜DATA2 is 16 KB which is still less than the predetermined size “32 KB”. Therefore, the controller 160 holds the write operations and does not write the data sectors DATA1˜DATA2 into the flash memory 180 at this moment. Next, the controller 160 continues to transmit a data-transmission request D_TRA_R3 corresponding to the write command W_COMM_3 to the host 120. After receiving the data-transmission request D_TRA_R3, the host 120 transmits the data sector DATA3 corresponding to the write command W_COMM_3 to the data storage device 140. The controller 160 stores the received data sector DATA3 in the random access memory 166, and determines whether the data sectors DATA1˜DATA3, which are stored in the random access memory 166 and have not been written into the flash memory, have reached the predetermined size. The total size of data sectors DATA1˜DATA3 is 24 KB which is still less than the predetermined size “32 KB”. Therefore, the controller 160 holds the write operations and does not write the data sectors DATA1˜DATA3 into the flash memory 180 at this moment. Next, the controller 160 continues to transmit a data-transmission request D_TRA_R4 corresponding to the write command W_COMM_4 to the host 120. After receiving the data-transmission request D_TRA_R4, the host 120 transmits the data sector DATA4 corresponding to the write command W_COMM_4 to the data storage device 140. The controller 160 stores the received data sector DATA4 in the random access memory 166, and determines whether the data sectors DATA1˜DATA4, which are stored in the random access memory 166 and have not been written into the flash memory, have reached the predetermined size. The total size of data sectors DATA1˜DATA4 is 32 KB which is equal to the predetermined size “32 KB”. Therefore, the controller 160 writes the data sectors DATA1˜DATA4, which are stored in the random access memory 166 and have not been written into the flash memory 180, into the flash memory 180 in the busy period NAND_Busy_1. It should be noted that, at the time that the controller 160 starts to write the data sectors DATA1˜DATA4 in to the flash memory 180, the controller 160 or the flash memory 180 sets the busy flag as a busy state. After the data sectors DATA1˜DATA4 are written into the flash memory 180, the controller 160 or the flash memory 180 sets the busy flag as an idle state. After setting the busy flag as an idle state, the controller 160 transmits the write-confirm signals Resp_1˜Resp_4 to the host 120 to notify the host 120 that the data sectors DATA1˜DATA4 of the write commands W_COMM_1˜W_COMM_4 are written into the flash memory 180. It should be noted that, in some embodiments, the data sectors which have been written into the flash memory 180 are removed from the random access memory 166. Next, the controller 160 continues to transmit a data-transmission request D_TRA_R5 corresponding to the write command W_COMM_5 to the host 120. After receiving the data-transmission request D_TRA_R5, the host 120 transmits the data sector DATA5 corresponding to the write command W_COMM_5 to the data storage device 140. The controller 160 stores the received data sector DATA5 in the random access memory 166, and determines whether the data sector DATA5, which are stored in the random access memory 166 and have not been written into the flash memory, has reached the predetermined size. The data sector DATA5 is the only data corresponding to the received write commands that is stored in the random access memory 166, such that total size of data sector DATA5, which is stored in the random access memory 166 and has not yet been written into the flash memory 180, is 8 KB which is still less than the predetermined size “32 KB”. However, the write command W_COMM_5 is the data of the last write command. Therefore, the controller 160 writes the data sector DATA5 stored in the random access memory 166 into the flash memory 180 in the busy period NAND_Busy_2. It should be noted that, at the time that the controller 160 starts to write the data sector DATA5 in to the flash memory 180, the controller 160 or the flash memory 180 sets the busy flag as a busy state. After the data sector DATA5 is written into the flash memory 180, the controller 160 or the flash memory 180 sets the busy flag as an idle state. After setting the busy flag as an idle state, the controller 160 transmits the write-confirm signal Resp_5 to the host 120 to notify the host 120 that the data sector DATA5 of the write command W_COMM_5 are written into the flash memory 180. As described above, the data sectors and write commands of the embodiment of FIG. 3 are the same as the embodiment of FIGS. 4A-4B. However, the data storage device 140 needs five busy periods to write the data sectors in the embodiment of FIG. 2, but the data storage device 140 only needs two busy periods to write the data sectors in the embodiment of FIG. 3. Moreover, in the embodiment of FIG. 2, the data sectors DATA1˜DATA5 are stored in five different pages, and the five pages written by the data sectors DATA1˜DATA5 cannot be written with other data. In the embodiment of FIG. 3, the data sectors DATA1˜DATA4 are stored in one page, and the data sector DATA5 is stored in another page. Namely, it only uses two pages to store the data sectors DATA1˜DATA5 in the embodiment of FIG. 3. Therefore, the embodiment of FIG. 3 has a faster write speed and better memory space usage than the embodiment of FIG. 2.

FIG. 4A-4B are a flowchart of a data writing method in accordance with an embodiment. The data writing method is applied to the data storage device 140 of FIG. 1. The process starts at step S400. It should be noted that, in this embodiment, the data storage device 140 operates in the cache-off mode of the specification of Embedded Multi Media Card and the specification of Universal Flash Storage.

In step S400, the controller 160 receives a plurality of write commands arranged to write a plurality of data sectors from the host 120.

Next, in step S402, the controller 160 transmits a data-transmission request corresponding to one of the received write commands to the host 120. For example, as shown in FIG. 3, the controller 160 receives the write commands W_COMM_1˜W_COMM_5 from the host 120 in step S400, wherein the write command W_COMM_1 is arranged to tell the data storage device 140 to write the data sector DATA1 into the flash memory 180, the write command W_COMM_2 is arranged to tell the data storage device 140 to write the data sector DATA2 into the flash memory 180, the write command W_COMM_3 is arranged to tell the data storage device 140 to write the data sector DATA3 into the flash memory 180, the write command W_COMM_4 is arranged to tell the data storage device 140 to write the data sector DATA4 into the flash memory 180, and the write command W_COMM_5 is arranged to tell the data storage device 140 to write the data sector DATA5 into the flash memory 180. Next, in step S402, the controller 160 selects one of the write commands W_COMM_1˜W_COMM_5 which has the data sector that has not yet been transmitted to the data storage device 140 to transmit the data-transmission request corresponding to the selected write command to the host 120.

Next, in step S404, the controller 160 receives the data sector corresponding to the transmitted data-transmission request from the host 120, and stores the received data sector in the random access memory 166. For example, as shown in FIG. 3, when the controller 160 transmits the data-transmission request D_TRA_R1 to the host 120 in step S402, the controller 160 receives the data sector DATA1 from the host 120 and stores the data sector DATA1 in the random access memory 166 in step S404.

Next, in step S406, the controller 160 determines whether the total size of data sectors, which are stored in the random access memory 166 and have not been written into the flash memory 180, has reached a predetermined size. In one of the embodiments, the predetermined size is equal to the size of the write unit (the minimum write unit) of the flash memory 180. For example, the write unit of the conventional flash memory 180 is a page, but it is not limited thereto. In other embodiments, the predetermined size may be designed according to the writing rule of the flash memory 180, wherein the minimum write unit of the flash memory 180 can also be a block or a sector. When the size of data sectors stored in the random access memory 166 has not reached the predetermined size, the process goes to step S412; otherwise, the process goes to step S408.

In step S408, the controller 160 determines whether any of the data sectors of the received write command has not yet been stored in the random access memory 166. When the controller 160 determines that at least one of the data sectors of the received write commands has not yet been stored in the random access memory 166, the process returns to step S402 to continue to transmit the data-transmission request to the host 120 to receive the data sector that has not yet been received. When the controller 160 determines that all of the data sectors of the received write commands have been stored in the random access memory 166, the process goes to step S410.

In step S410, the controller 160 determines whether the random access memory 166 has any data sectors that have not yet been written into the flash memory 180. When the random access memory 166 has at least one data sector that has not yet been written into the flash memory 180, the process goes to step S412; otherwise, the process goes to step S410.

In step S412, the controller 160 starts to write the data sectors stored in the random access memory 166 into the flash memory 180. It should be noted that, in one embodiment, at the time that the controller 160 starts to write the data sectors in to the flash memory 180, the controller 160 or the flash memory 180 sets the busy flag as a busy state. After the data sectors are written into the flash memory 180, the controller 160 or the flash memory 180 sets the busy flag as an idle state.

Next, in step S414, the controller determines whether the flash memory 180 is idle. When the flash memory 180 is idle, the process goes to step S416; otherwise, the controller 160 continues to determine whether the flash memory 180 is idle. In one of the embodiments, the controller 160 determines whether the flash memory is idle according to the busy flag, but it is not limited thereto.

In step S416, the controller 160 transmits the write-confirm signal corresponding to the written data sectors to the host 120 to notify the host 120 that the data sectors are written into the flash memory 180. More specifically, as shown in FIG. 3, the controller 160 writes the data sectors DATA1˜DATA4 into the flash memory 180 in step S412. Next, in step S416, the controller 160 transmits the write-confirm signals Resp_1˜Resp_4 of the data sectors DATA1˜DATA4 to the host 120 to the host 120 to notify the host 120 that the data sectors DATA1˜DATA4 of the write commands W_COMM_1˜W_COMM_4 are written into the flash memory 180. In another embodiment, as shown in FIG. 3, the controller 160 writes the data sector DATA5 into the flash memory 180 in step S412. Next, in step S416, the controller 160 transmits the write-confirm signal Resp_5 to the host 120 to notify the host 120 that the data sector DATA5 of the write command W_COMM_5 is written into the flash memory 180. Next, the process returns to step S406 to continue to determine whether the total size of the data sectors stored in the random access memory 166 that has not yet been written into the flash memory 180 has reached the predetermined size.

The data storage device and the data writing method of the present invention can write the data sectors of a plurality of write commands into the flash memory at once to increase the write efficiency of the data storage device. More specifically, the data storage device and the data writing method of the present invention decrease the time needed to write random data into the flash memory and write the random data into a page rather than a plurality of pages in a concentrated fashion.

Data transmission methods, or certain aspects or portions thereof, may take the form of program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes an apparatus for practicing the methods. The methods may also be embodied in the form of program code transmitted over some transmission medium, such as electrical wiring or cabling, through fiber optics, or via any other form of transmission, wherein, when the program code is received and loaded into and executed by a machine such as a computer, the machine becomes an apparatus for practicing the disclosed methods. When implemented on a general-purpose processor, the program code combines with the processor to provide a unique apparatus that operates analogously to application-specific logic circuits.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A data storage device, comprising:
a flash memory; and
a controller, receiving a plurality of write commands arranged to write a plurality of data sectors into the flash memory from a host, receiving the data sectors from the host in sequence according to the received write commands, wherein during the period of receiving the data sectors, the controller records that the received data sectors have not been confirmed when total size of received data sectors has not reached a predetermined size, writes a plurality of specific data sectors of the data sectors, which have been received from the host, into the flash memory when the total size of received data sectors has reached the predetermined size, and transmits a plurality of write-confirm signals corresponding to the specific data sectors to the host after all of the specific data sectors are written into the flash memory.

2. The data storage device as claimed in claim 1, wherein the predetermined size is equal to the write unit of the flash memory.

3. The data storage device as claimed in claim 2, wherein the write unit of the flash memory is a page.

4. The data storage device as claimed in claim 1, wherein the data storage device operates in a cache-off mode of the specification of Embedded Multi Media Card or the specification of Universal Flash Storage (UFS).

5. The data storage device as claimed in claim 1, wherein each of the write-confirm signals is arranged to notify the host that the corresponding specific data sector is written into the flash memory.

6. A data storage device, comprising:
a flash memory; and
a controller, receiving a switch signal from a host, and operating in a cache-off mode of the specification of Universal Flash Storage or specification of Embedded Multi Media Card in response to the switch signal, wherein in the cache-off mode, the controller writes a plurality of specific data sectors, which are indicated by a plurality of first write commands, into the flash memory, and transmits a plurality of write-confirm signals corresponding to the first write commands to a host after all of the specific data sectors are written into the flash memory.

7. The data storage device as claimed in claim 6, wherein the controller receives a plurality of write commands arranged to write a plurality of data sectors from the host, receives the data sectors from the host in sequence according to the received write commands, and writes the specific data sectors of the data sectors into the flash memory when the size of specific data sectors, which are the received data sectors, reaches a predetermined size.

8. The data storage device as claimed in claim 7, wherein during the period from writing the first of the specific data sectors into the flash memory to writing the last of the specific data sectors into the flash memory, a busy flag, which is arranged to represent whether the flash memory is busy, maintains a value of busy status.

9. The data storage device as claimed in claim 7, wherein the predetermined size is the write unit of the flash memory, and the write unit of the flash memory is a page.

10. The data storage device as claimed in claim 6, wherein each of the write-confirm signals is arranged to notify the host that the corresponding specific data sector has been written into the flash memory.

11. A data writing method, applied to a data storage device having a flash memory, comprising:
receiving a plurality of write commands arranged to write a plurality of data sectors into the flash memory from a host;
receiving the data sectors from the host in sequence according to the received write commands;
recording the received data sectors that have not been confirmed when total size of received data sectors has not reached a predetermined size;
writing a plurality of specific data sectors of the data sectors, which have been received from the host, into the flash memory when the total size of received data sectors has reached the predetermined size; and
transmitting a plurality of write-confirm signals corresponding to the specific data sectors to the host after all of the specific data sectors are written into the flash memory.

12. The data writing method as claimed in claim 11, wherein the predetermined size is equal to the write unit of the flash memory.

13. The data writing method as claimed in claim 12, wherein the write unit of the flash memory is a page.

14. The data writing method as claimed in claim 11, wherein the data storage device operates in a cache-off mode of the specification of Embedded Multi Media Card or the specification of Universal Flash Storage (UFS).

15. The data writing method as claimed in claim 11, wherein each of the write-confirm signals is arranged to notify the host that the corresponding specific data sector is written into the flash memory.

16. A data writing method, applied to a data storage device having a flash memory, comprising:
receiving a switch signal from a host, and operating in a cache-off mode of the specification of Universal Flash Storage or specification of Embedded Multi Media Card in response to the switch signal, wherein in the cache-off mode the data writing method further comprises:
writing a plurality of specific data sectors, which are indicated by a plurality of first write commands, into the flash memory; and
transmitting a plurality of write-confirm signals corresponding to the first write commands to a host after all of the specific data sectors are written into the flash memory.

17. The data writing method as claimed in claim 16, wherein the step of writing the data sectors indicated by the write commands into the flash memory further comprises:
receiving a plurality of write commands arranged to write a plurality of data sectors from the host;
receiving the data sectors from the host in sequence according to the received write commands; and
writing the specific data sectors of the data sectors into the flash memory when the size of specific data sectors, which are the received data sectors, reaches a predetermined size.

18. The data writing method as claimed in claim 17, wherein during the period from writing the first of the specific data sectors into the flash memory to writing the last of the specific data sectors into the flash memory, a busy flag, which is arranged to represent whether the flash memory is busy, maintains a value of busy status.

19. The data writing method as claimed in claim 17, wherein the predetermined size is the write unit of the flash memory, and the write unit of the flash memory is a page.

20. The data writing method as claimed in claim 16, wherein each of the write-confirm signals is arranged to notify the host that the corresponding specific data sector is written into the flash memory.
